(19) United States
(12) Patent Application Publication
(10) Pub. No.: US 2024/0071805 A1
(43) Pub. Date: Feb. 29, 2024

(54) METHOD, ASSEMBLY AND SYSTEM FOR GAS INJECTION

(71) Applicant: ASM IP Holding B.V., Almere (NL)

(72) Inventors: Han Ye, Phoenix, AZ (US); Peipei Gao, Chandler, AZ (US); Wentao Wang, Chandler, AZ (US); Aniket Chitale, Phoenix, AZ (US); Xing Lin, Chandler, AZ (US); Alexandros Demos, Scottsdale, AZ (US); Yanfu Lu, Phoenix, AZ (US)

(21) Appl. No.: 18/238,577

(22) Filed: Aug. 28, 2023

Related U.S. Application Data
(60) Provisional application No. 63/402,870, filed on Aug. 31, 2022.

(51) Int. Cl. H01L 21/687; H01L 21/67

(52) U.S. Cl. CPC H01L 21/68735; H01L 21/67069

(57) ABSTRACT

Methods, systems, and assemblies suitable for gas-phase processes are disclosed. An exemplary assembly includes a susceptor ring and at least one injector tube. The injector tube can be disposed within the susceptor ring to provide a gas to a lower chamber area of a reactor. Methods, systems, and assemblies can be used to obtain desired etching and purging of the lower chamber area.

### CROSS-REFERENCE TO RELATED APPLICATIONS

This application is a nonprovisional of, and claims priority to and the benefit of, U.S. Provisional Patent Application No. 63/402,870, filed Aug. 31, 2022 and entitled “METHOD, ASSEMBLY AND SYSTEM FOR GAS INJECTION,” which is hereby incorporated by reference herein.

### FIELD OF INVENTION

The present disclosure generally relates to methods, assemblies and systems used in the formation of electronic devices. More particularly, the disclosure relates to methods, assemblies, and systems suitable for providing a gas to a lower area of a reaction chamber.

### BACKGROUND OF THE DISCLOSURE

Gas-phase reactors, such as chemical vapor deposition (CVD) reactors and the like, can be used for a variety of applications, including depositing, and etching materials on a substrate surface, and cleaning of a surface of the substrate. For example, gas-phase reactors can be used to deposit epitaxial layers on a substrate to form devices, such as semiconductor devices, flat panel display devices, photovoltaic devices, microelectromechanical systems (MEMS), and the like.

A typical gas-phase epitaxial reactor system includes a reactor including a reaction chamber, one or more precursor and/or reactant gas sources fluidly coupled to the reaction chamber, one or more carrier and/or purge gas sources fluidly coupled to the reaction chamber, a gas injection system to deliver gases (e.g., precursor/reactant gas(es) and/or carrier/purge gas(es)) to the reaction chamber, a susceptor to retain and heat a substrate, and an exhaust source fluidly coupled to the reaction chamber. Additionally, the system can further include a lift pin assembly that includes lift pins that move through apertures within the susceptor to raise and lower a substrate onto the susceptor. Further, epitaxial reactor systems can include one or more heaters (e.g., lamps) and/or temperature measurement devices (e.g., a thermocouple).

In some cases, the reaction chamber can be seasoned prior to introducing a susceptor within the reaction chamber. The seasoning can include depositing a thin layer of material onto the susceptor. During this step, the material can be deposited within the apertures within the susceptor and/or on the lift pins, which can cause the lift pins to stick and not function properly. Improved methods, systems, and assemblies are therefore desired.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to improved methods, assemblies and systems suitable for providing a gas to a lower chamber area and/or an upper chamber area of a reaction chamber. The gas can be used to, for example etch and/or purge the lower chamber area of a reaction chamber. While the ways in which various embodiments of the present disclosure address drawbacks of prior systems and methods are discussed in more detail below, in general, various embodiments of the disclosure provide methods, assemblies and systems that can be used to, for example, reduce buildup of materials on a lower surface of a susceptor and/or lift pins which are used during substrate processing and/or cleaning/etching a lower chamber area independent from cleaning or etching an upper chamber area. Examples of the disclosure can reduce buildup on lift pins and/or within the susceptor apertures that might otherwise occur, which can increase throughput and reduce cost of ownership of reactor systems.

Examples of the disclosure are conveniently described in connection with formation of epitaxial films, such as silicon and/or silicon germanium films, or other grown or deposited layers. However, unless noted otherwise, examples of the disclosure are not so limited.

In accordance with embodiments of the disclosure, a susceptor ring assembly is provided. The susceptor ring assembly can provide gas to the lower chamber area to mitigate the unwanted buildup of material within the lower chamber area and/or within a susceptor. The susceptor ring assembly can provide gas to the upper chamber area to mitigate unwanted buildup of material within the upper chamber area and/or on an interior surface of an upper wall of the chamber. An exemplary susceptor ring assembly comprises a susceptor ring and at least one injector tube. An exemplary susceptor ring includes a top surface, a bottom surface, a first edge, a second edge, and a susceptor opening at the interior of the susceptor ring. In accordance with examples of embodiments, the first edge can comprise an opening extending to a first injector cavity within the susceptor ring. In accordance with examples of embodiments, one or more of the upper surface, the bottom surface, and a sidewall surface of the susceptor ring comprise one or more first outlets. In accordance with additional embodiments, the first injector tube can be at least partially disposed within the first injector cavity.

In accordance with further exemplary embodiments, the susceptor ring can comprise a second injector cavity and a second injector tube disposed therein. In accordance with examples of embodiments, the first and/or second injector tube can comprise quartz. The susceptor ring can further comprise one or more second outlets.

In accordance with additional embodiments of the disclosure, the one or more first and/or second outlets comprise substantially vertical outlets spanning a portion of the bottom surface. In accordance with additional embodiments of the disclosure, the one or more first and/or second outlets comprise substantially horizontal outlets spanning a portion of the sidewall surface. In accordance with additional embodiments of the disclosure, the one or more first and/or second outlets comprise corner outlets spanning a portion of the bottom surface and a portion of the sidewall.

In accordance with yet further examples of embodiments, the susceptor ring assembly can further comprise a rotatable susceptor at least partially disposed within the susceptor opening. The susceptor may be supported for rotation relative to the susceptor ring about a rotation axis.

In accordance with additional examples of embodiments, an (e.g. first and/or second) injector tube can comprise an aperture within a wall of the injector tube. The aperture can be in fluid communication with at least one of the one or more (e.g. first and/or second) outlets.

In accordance with additional embodiments of the disclosure, a reactor system is provided. The reactor system includes a reactor comprising a reaction chamber. The reactor can include an upper chamber area, a lower chamber area, and a susceptor ring assembly disposed within the reaction chamber. The susceptor ring assembly can be the same susceptor ring assembly as described above and elsewhere herein.

In accordance with example of embodiments, the reactor system comprises a rotatable susceptor at least partially disposed within the susceptor opening. The rotatable susceptor can comprise a susceptor top surface and a susceptor bottom surface. Further, the rotatable susceptor can comprise one or more lift pin apertures and at least one lift pin can be received by one of the one or more lift pin apertures.

In accordance with examples of embodiments, an etchant source can be fluidly coupled to the first and/or second injector tube. The etchant source can comprise an etchant, such as a halide-containing material. Examples of suitable halide-containing materials include chlorine (Cl₂) gas and, hydrochloric (HCl) acid.

In accordance with examples of embodiments, the reactor system further comprises an exhaust flange coupled to a first end of the reaction chamber. In accordance with examples of embodiments, the reactor system comprises an injection flange, wherein the injection flange is coupled to a second end of the reaction chamber.

In accordance with examples of embodiments, a purge gas source comprising a purge gas can be fluidly coupled to the first and/or second injector tube. The purge gas can comprise one or more of hydrogen (H₂) gas, nitrogen (N₂) gas, an inert gas such as argon (Ar) or helium (He) gas, and any mixtures thereof.

In accordance with additional embodiments of the disclosure, a method is provided. An exemplary method includes providing a susceptor ring assembly within a reaction system. The reactor system can comprise a reactor comprising an upper chamber area and a lower chamber area. In accordance with examples of embodiments, the susceptor ring assembly can be a susceptor ring assembly as described above or elsewhere herein. In accordance with examples of embodiments, the method further comprises providing a gas through an injector tube (e.g. first and/or second injector tube) to the lower chamber area. The gas can be one or more of an etchant and a purge gas as described herein.

In accordance with yet further examples of embodiments, the method further comprises providing a second gas to the upper chamber area before, during, and/or after the step of providing the first gas. In accordance with examples of embodiments, the second gas include, for example, a cleaning reactant, a precoat precursor, and/or a deposition precursor.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates an isometric view of a susceptor ring assembly in accordance with exemplary embodiments of the disclosure.

FIG. 2 illustrates a portion of a susceptor ring assembly in accordance with exemplary embodiments of the disclosure.

FIG. 3 illustrates a portion of an injector tube in accordance with exemplary embodiments of the disclosure.

FIG. 4 illustrates a portion of a susceptor ring assembly in accordance with exemplary embodiments of the disclosure.

FIG. 5 illustrates a portion of a susceptor ring assembly in accordance with exemplary embodiments of the disclosure.

FIG. 6 illustrates a portion of a susceptor ring assembly in accordance with exemplary embodiments of the disclosure

FIG. 7 illustrates a cross sectional view of a reactor system in accordance with exemplary embodiments of the disclosure.

FIG. 8 illustrates a portion of a gas inlet in accordance with exemplary embodiments of the disclosure.

FIG. 9 illustrates a method in accordance with exemplary embodiments of the disclosure.

FIG. 10 illustrates an isometric view of another susceptor ring assembly in accordance with exemplary embodiments of the disclosure.

FIG. 11 illustrates another method in accordance with exemplary embodiments of the disclosure.

It will be appreciated that elements in the figures are illustrated for simplicity and clarity and have not necessarily been drawn to scale. For example, the dimensions of some of the elements in the figures can be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to methods, assemblies and systems suitable for use in gas-phase reactors. Such methods, assemblies, and systems can be used to deliver an etchant and/or purge gases to a lower chamber area of a reactor to remove or mitigate formation of material, such as precoat, seasoning, or other pretreatment materials from lift pins and the bottom surface of a susceptor or other surfaces in a lower chamber area of a reactor.

As used herein, the terms “precursor” and/or “reactant” can refer to one or more gases/vapors that take part in a chemical reaction or from which a gas-phase substance that takes part in a reaction is derived. The terms precursor and reactant can be used interchangeably. The chemical reaction can take place in the gas phase and/or between a gas phase and a surface (e.g., of a substrate or reaction chamber) and/or a species on a surface (e.g., of a substrate or a reaction chamber). A dopant can be considered a precursor or reactant.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may comprise, or may consist at least partially of, a plurality of dispersed atoms on a surface of a substrate and/or may be or may become embedded in a substrate. A film or layer may comprise material or a layer with pinholes and/or isolated islands. A film or layer may be at least partially continuous. In some cases, a film can include two or more layers.

The term “deposition process” as used herein can refer to the introduction of precursors (and/or reactants) into a reaction chamber to deposit or form a layer over a substrate.

In this disclosure, any two numbers of a variable can constitute a workable range of the variable, and any ranges indicated can include or exclude the endpoints. Additionally, any values of variables indicated (regardless of whether they are indicated with “about” or not) can refer to precise values or approximate values and include equivalents, and can refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

As noted above, examples of the disclosures are suitable for use with various gas phase processes. In many gas phase processes, such as thermal CVD or ALD and the like, a pretreatment process is used to improve film quality of layers on a substrate and substrate-to-substrate film thickness and/or composition uniformity. Such pretreatments may be particularly desirable for epitaxial processes—e.g., used in the formation of gate-all-around, DRAM devices, or the like. A pretreatment process typically includes deposition of pretreatment layers (e.g. Si and SiGe) on the susceptor before the substrate is transferred to the susceptor for processing. In reactor systems that employ lift pins, pretreatment material can cause buildup and consequently friction between lift pins and the susceptor (sometimes referred to as lift pin binding), when such material is deposited on the lift pin and/or within a susceptor aperture through which the lift pin moves. The presence of pretreatment layers, and other materials deposited during a deposition process can thus reduce the lift pin's ability to move up and down through the susceptor lift pin aperture to transfer wafers. To avoid damage to the lift pins, the susceptor, and/or the substrate caused by pin binding, methods, assemblies, and systems described herein can provide an etchant and/or a purge gas to a lower portion of the lift pin and bottom surface of the susceptor to remove such materials.

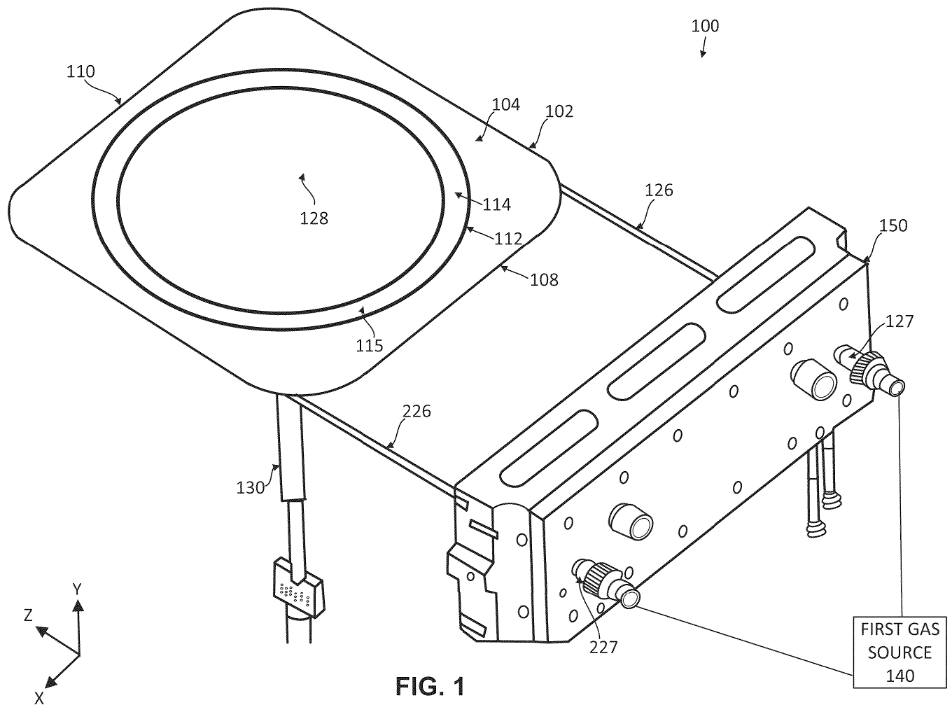

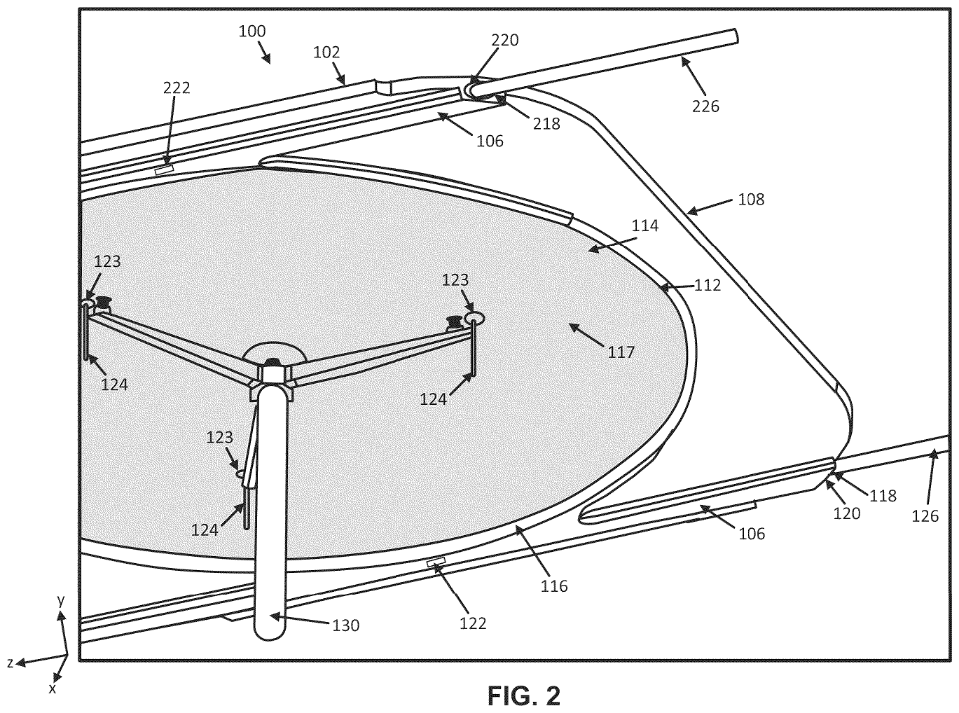

Turning now to the figures, FIGS. 1-2 illustrate views of an exemplary susceptor ring assembly 100, which can be used to provide gas to a lower chamber area. The susceptor ring assembly 100 comprises a susceptor ring 102 and one or more injector tubes 126, 226. In the illustrated example, the susceptor ring 102 includes a top surface 104, a bottom surface 106 (shown in FIG. 2), a first edge 108, a second edge 110 and a susceptor opening 112 at an interior of the susceptor ring 102. The susceptor opening 112 can be a circular opening centered within the susceptor ring 102. In various embodiments, a susceptor 114 can be at least partially disposed within the susceptor opening 112. Susceptor ring 102 can include a sidewall surface 116 as further illustrated, extending along the circumference of the susceptor opening 112 from the top surface 104 to the bottom surface 106. Susceptor ring 102 can be formed of, for example, bulk graphite or a pyrolytic carbon material. The bulk graphite or pyrolytic carbon material may have (or be encapsulated in) a silicon carbide coating.

Susceptor 114 is configured to receive and retain a substrate 128. The susceptor 114 can comprise a susceptor top surface 115 and a susceptor bottom surface 117 (shown in FIG. 2). One or more lift pin apertures 123 can be disposed within the susceptor 114, wherein the one or more lift pin apertures 123 span from the susceptor top surface 115 to the susceptor bottom surface 117. In various embodiments, at least one of the one or more lift pin apertures 123 is configured to receive a lift pin 124. The lift pin 124 can translate up and down to load and unload a substrate 128 from the susceptor 114.

Susceptor ring assembly 100 further comprises a first opening 118 that extends to a first injector cavity 120. First injector cavity 120 can extend from first edge 108 to a distance from first edge 108. For example, first injector cavity 120 can extend from about 30 millimeters to about 250 millimeters from first edge 108. In various embodiments, the susceptor ring assembly 100 can further comprise a second opening 218 that extends to a second injector cavity 220. Second injector cavity 220 can extend from first edge 108 to a distance from first edge 108 that is the same distance as that of the first injector cavity 120.

As shown in FIG. 2, the bottom surface 106 can comprise one or more first outlets 122 and/or one or more second outlets 222. A first injector tube 126 can be disposed within the first injector cavity 120 and the first injector tube 126 can be in fluid communication with the one or more first outlets 122. A second injector tube 226 can be disposed within the second injector cavity 220 and the second injector tube 226 can be in fluid communication with the one or more second outlets 222.

Although illustrated with two injector tubes 126 and 226, assemblies, such as susceptor ring assembly 100, in accordance with the disclosure can include any suitable number of injector tubes.

The first injector cavity 120 is configured to deliver a first gas to a lower chamber area of a reaction chamber, through the one or more first outlets 122, such that the first gas is delivered from the first injector tube 126 through the one or more first outlets 122 and to the lower chamber area. In various embodiments, the second injector cavity 220 can be configured to deliver the first gas to the lower chamber area through the one or more second outlets 222, such that the first gas is delivered from the second injector tube 226 delivered through the one or more second outlets 222 and to the lower chamber area. The first gas can be supplied to the system from a first gas source 140 in fluid communication with the first injector tube 126 and/or the second injector tube 226. The first gas source 140 can be an etchant source, such that it provides an etchant to the susceptor ring assembly 100. The etchant can comprise chlorine (Cl₂) gas, hydrochloric (HCl) acid, a hydrochloric acid (HCl) precursor or combinations thereof, or along with a carrier or dilution gas (e.g. a noble gas).

In various embodiments, the first injector tube 126 and/or the second injector tube 226 comprises quartz or other suitable materials for gas delivery. In exemplary embodiments, a proximal portion 127 of the first injector tube 126 and a proximal portion 227 of the second injector tube 226 are both (e.g. sealably) coupled to an exhaust flange 150. The first gas source 140 can be in fluid communication with the proximal portion 127 of the first injector tube 126 and the proximal portion 227 of the second injector tube 226.

In various embodiments, the susceptor 114 can also be configured to rotate (or not) during processing by a rotational motor system 130 coupled to the susceptor 114. In accordance with examples of the disclosure, susceptor 114 rotates at a speed of about 60 to about 2, about 35 to about 2, or about 35 to about 15 rotations per minute.

In some cases, the one or more first outlets 122 and the one or more second outlets 222 can have a cross-sectional dimension between about 3 millimeters and about 20 millimeters. The dimensions, and/or the positioning of the outlets 122 and 222 can be tuned to provide desired flow characteristic for etchant and purge gas injection to the susceptor bottom surface 117, the lift pins 124, and/or other surfaces. In some cases, at least one of the outlets 122 and 222 can be configured to deliver substantially radial flow of gases to the susceptor bottom surface 117 and the lift pins 124 by providing the first gas at an area about equal distant (e.g. within about 10%, 5% or 2%) of a location midway between a leading or distal edge of the susceptor 114 and a trailing or proximal edge of the susceptor 114 and outside (away) from the perimeter of the susceptor 114.

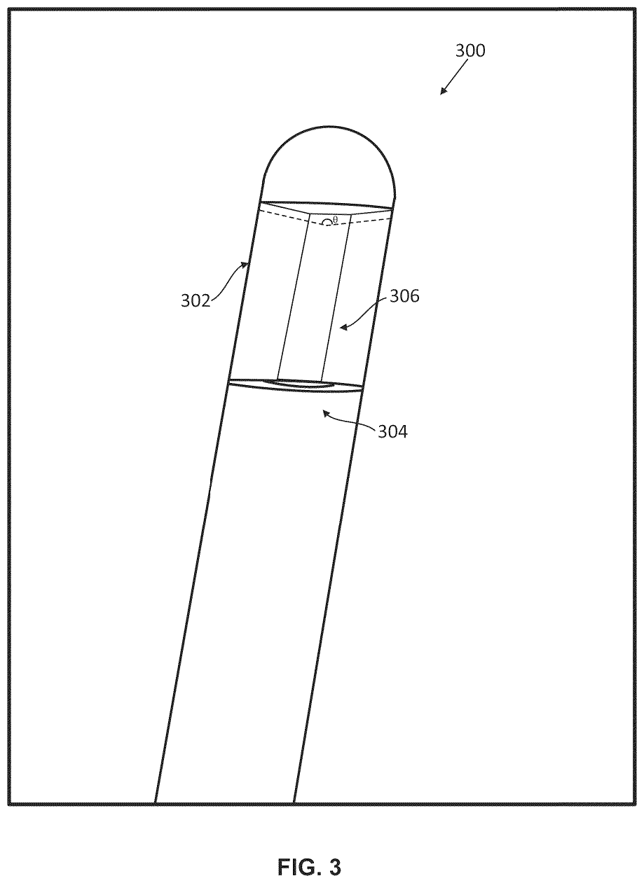

With additional reference to FIG. 3, a portion of an exemplary injector tube 300 is illustrated. Injector tube 300 can be used for one or more of the first injector tube 126 and the second injector tube 226. Injector tube 300 comprises an aperture 302 within a wall 304 of the injector tube 300. In the illustrated example, the aperture 302 is cut out of the injector tube 300 such that there is an opening angle (θ) 306. The opening angle θ can be between about 120 degrees and bout 70 degrees, or about 80 degrees and about 100 degrees, or about 90 degrees. Although illustrated with one aperture 302, injector tube 300 can comprise multiple apertures. For example, the injector tube 300 can include 1 to 10 or 2 to 5 apertures. In various embodiments, the number of apertures 302 is equal to the number of outlets on the bottom surface 106 or sidewall surface 116.

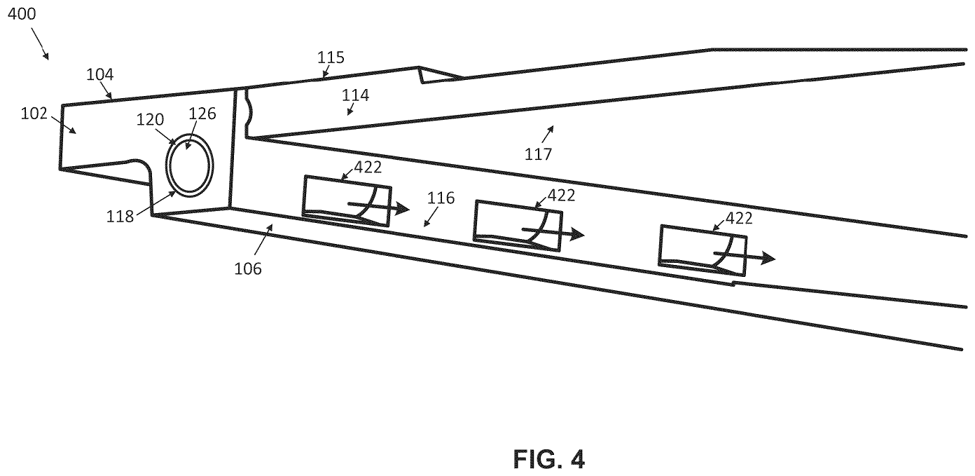

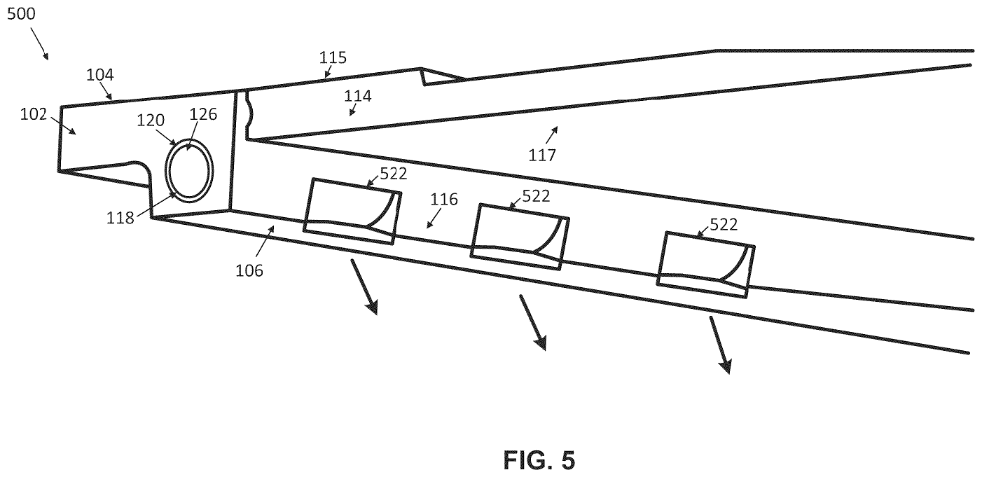

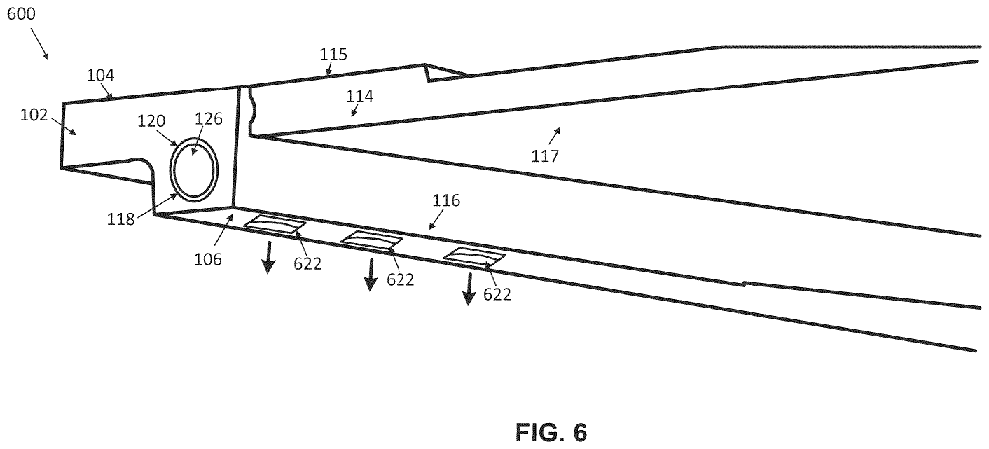

With additional reference to FIGS. 4-6, susceptor ring assemblies 400, 500, and 600 in accordance with various examples of the disclosure are illustrated. Susceptor ring assemblies 400, 500, and 600 have the same components of susceptor ring assembly 100; however they are illustrated to show different configurations of the one or more outlets 122, 222.

Susceptor ring assembly 400 illustrates an exemplary embodiment, where one or more horizontal outlets 422 span a portion of the sidewall surface 116 of the susceptor ring 102. The one or more horizontal outlets 422 are configured to deliver a substantially horizontal flow of the first gas to the lower chamber area of the reaction space. The substantially horizontal flow of gas can at least initially flow about parallel to the susceptor bottom surface 117 and can be substantially perpendicular to a process gas ((e.g. about 90 degrees plus/minus 10 degrees, 5 degrees or 2 degrees).

Susceptor ring assembly 500 illustrates an exemplary embodiment, where one or more corner outlets 522 span a portion of the bottom surface 106 and a portion of the sidewall surface 116 of the susceptor ring 102. The one or more corner outlets 522 are configured to deliver an angular flow of the first gas to the lower chamber area of the reaction space. The substantially angular flow of gas is between about 1 degree and about 89 degrees from a plane parallel to the susceptor bottom surface 117 and a plane parallel to the sidewall surface 116.

Susceptor ring assembly 600 illustrates an exemplary embodiment, where one or more vertical outlets 622 span a portion of the bottom surface 106 of the susceptor ring 102. The one or more vertical outlets 622 are configured to deliver a substantially vertical flow of the first gas to the lower chamber area of the reaction space. The substantially vertical flow of gas moves about parallel (e.g. ±10 degrees, 5 degrees, or 2 degrees) to the sidewall surface 116.

Susceptor ring assembly 100 can use one or more of the configurations of outlets as shown in susceptor ring assemblies 400, 500, and 600. For example, the one or more first outlets 122 can comprise the one or more horizontal outlets 422, while the one or more second outlets 222 can comprise the one or more vertical outlets 622. Although illustrated with one outlet 122 and 222, assemblies, such as susceptor ring assembly 100, in accordance with the disclosure can include any suitable number of outlets.

In various embodiments, each of the one or more outlets 122, 222, 422, 522, and 622 are below the susceptor bottom surface 117. The placement of said outlets is configured to provide the purge gas or etchant in a lower chamber area of the reaction space. The one or more first outlets 122 and the one or more second outlets 222 each can independently comprise the configurations of the horizontal outlets 422, the corner outlets 522, and the vertical outlets 622 in any combination.

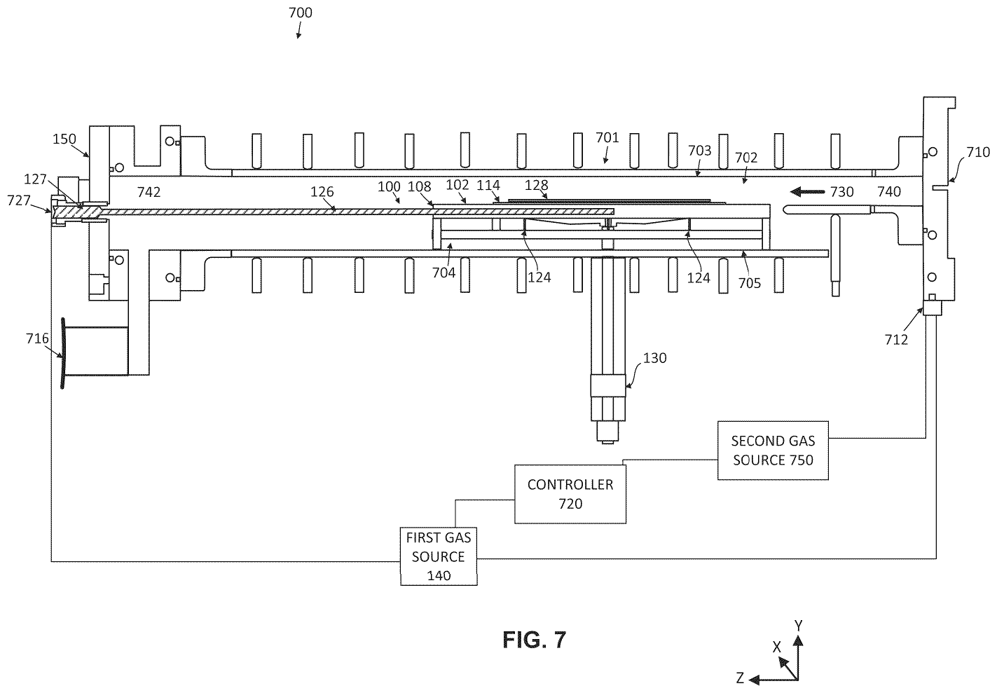

With reference to FIG. 7, a cross-section view of an exemplary reactor system 700 according to an embodiment of the present disclosure is illustrated. The reactor system 700 can comprise a reactor 701 with a first end 740 of the reactor 701 comprising an injection flange 710, and a second end 742 of the reactor 701 comprising an exhaust flange 150. The reactor 701 further comprises a reaction chamber upper wall 703 and a reaction chamber lower wall 705. The reactor system 700 comprises the susceptor ring assembly 100 as described above. The reactor 701 comprises an upper chamber area 702 defined as the volume between the susceptor ring 102 and the reaction chamber upper wall 703. Further, the reactor 701 comprises a lower chamber area 704 defined as the volume between the susceptor ring 102 and the reaction chamber lower wall 705.

The substrate 128 can be provided in the reactor 701 on the susceptor 114. In various embodiments, the substrate 128 can be lifted above the susceptor 114 and lowered on to the susceptor 114 for processing with one or more lift pins 124. In various embodiments, an exhaust port 716 is fluidly coupled at the second end 742 of the reactor 701 to remove process gases and precursors from the reaction chamber.

The injection flange 710 can comprise a gas inlet 712 configured to introduce gas (e.g. the second gas and optionally the first gas) to the reactor system 700 through the injection flange 710 into the first end 740 of the reactor 701. The gas inlet 712 is in fluid communication with a second gas source 750 and optionally the first gas source 140. A gas inlet 727 of the first injector tube 126 and a gas inlet of the second injector tube 226 can be at the second end 742 of the reactor 701, wherein the gas inlets of the injector tubes are in fluid communication with the first gas source 140. A gas flow 730 represents the flow direction of the gas entering the reaction chamber at the first end 740 of the reactor 701.

The second gas source 750 can comprise a second gas and/or a third gas. The second gas source 750 can be in fluid communication with the injection flange 710, wherein the injection flange 710 is configured to introduce the second gas and/or the third gas to the upper chamber area 702 of the reactor 701 through the gas inlet 712.

In some embodiments, at least one of the second gas and the third gas comprises a precursor. The precursor may comprise a silane, such as, for example, silane (SiH₄), disilane (Si₂H₆), trisilane (Si₃H₈), tetrasilane (Si₄H₁₀) or higher order silanes with the general empirical formula SiₓH₍₂ₓ₊₂₎. In some cases, the precursor can be a halogenated precursor. By way of examples, the precursor can be or include one or more of silicon tetrachloride (SiCl₄), trichloro-silane (SiCl₃H), dichlorosilane (SiCl₂H₂), monochlorosilane (SiClH₃), hexachlorodisilane (HCDS), octachlorotrisilane (OCTS), a silicon iodide, a silicon bromide. In some cases, the precursor can be an amino-based precursor, such as hexakis(ethylamino)disilane (AHEAD) and SiH[N(CH₃)₂]₃(3DMASi), a bis(dialkylamino)silane, such as BDEAS (bis(diethylamino)silane); a mono(alkylamino)silane, such as di-isopropylaminosilane; or an oxysilane based precursor, such as tetraethoxysilane Si(OC₂H₅)₄.

Additionally or alternatively, one or more of the second gas and the third gas can comprise a carrier gas, such as an inert gas. In some cases, one or more of the second gas and the third gas can include a dopant. Exemplary dopant sources include gases that include one or more of arsenic (As), phosphorus (P), carbon (C), germanium (Ge), and boron (B). By way of examples, the dopant source can include germane, diborane, phosphine, arsine, or phosphorus trichloride.

In various embodiments, a controller 720 can be in electronic communication with the first gas source 140 and the second gas source 750. The controller 720 can be configured to perform various functions and/or steps as described herein. Controller 720 can include one or more microprocessors, memory elements, and/or switching elements to perform various functions, such as deliver gases to the reactor system 700 from one or more of the first gas source 140 and the second gas source 750. Although illustrated as a single unit, controller 720 can alternatively comprise multiple devices. By way of examples, controller 720 can be used to control gas flow (e.g., by monitoring flow rates of precursors and/or other gases from the gas sources 140 and 750 and/or controlling valves, motors, heaters, and the like).

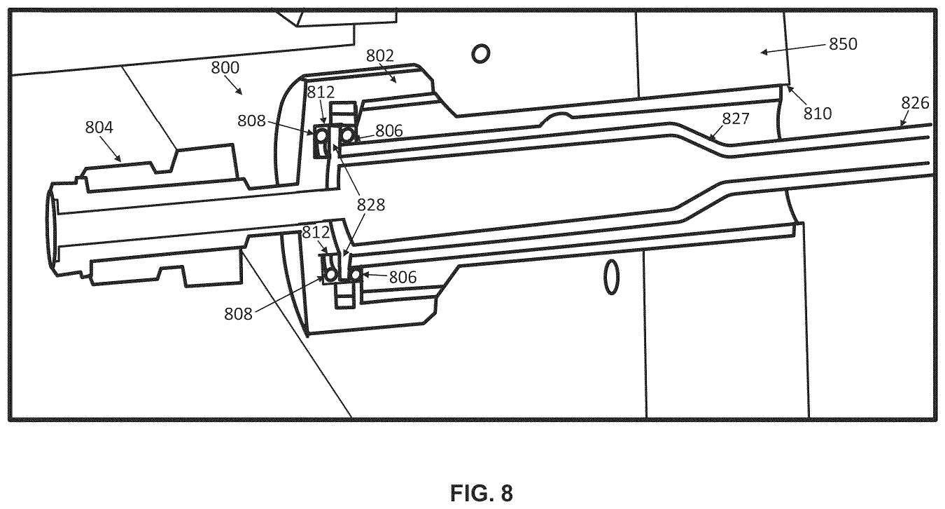

With reference to FIG. 8, a portion of an exemplary gas connector assembly 800 is illustrated. Gas connector assembly 800 can be used to couple an injector tube 826 (same or similar to first injector tube 126 and the second injector tube 226) to an exhaust flange 850 (same or similar to exhaust flange 150). Gas connector assembly 800 comprises a nut 802 coupled to an exhaust flange opening 810 of the exhaust flange 850 and a portion of the nut 802 is disposed on the outside of the exhaust flange 850. The nut 802 can comprise connector cavity 812 at a distal end of the nut 802. In various embodiments, the injector tube 826 can also comprise a proximal portion 827 (same similar to proximal portions 127 and 227) of the injector tube 826. The proximal portion 827 of the injector tube 826 has an increased diameter when compared with the rest of the injector tube 826. The proximal portion 827 of the injector tube 826 can be substantially encased by the nut 802 and the exhaust flange 850.

Additionally, the injector tube 826 can comprise a tube flange 828 at the end of the proximal portion 827 of the injector tube 826, the tube flange 828 can comprise a lip that wraps around the end of the proximal portion 827 of the injector tube 826. Injector tube 826 can be coupled to the nut 802 by placing the tube flange 828 into the connector cavity 812 and compressing the sides of the tube flange 828 with a first o-ring 806 and a second o-ring 808 placed between the connector cavity 812 and each side of the tube flange 828. The o-rings 806, 808 put pressure against the tube flange 828 to secure the tube flange 828 and the injector tube 826 in place.

The gas connector assembly 800 can further comprise a VCR connector 804 coupled to the nut 802. In some embodiments the VCR connector 804 is welded to the nut 802. The VCR connector 804 can be in fluid communication with a gas source, such as the first gas source 140, and the proximal portion 827 of the injector tube 826. The gas connector assembly 800 can be used in FIG. 1 to secure each of the proximal portions 127 and 227 of the injector tubes 126 and 226 to the exhaust flange 150.

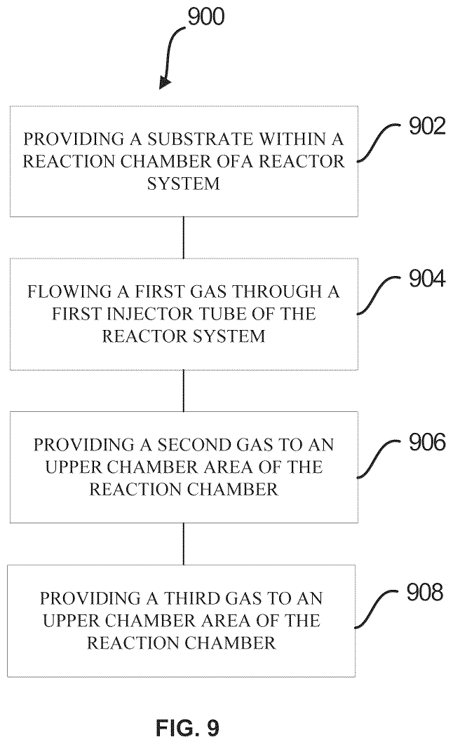

With reference to FIG. 9, a method 900 according to embodiments of the disclosure is illustrated. Method 900 includes a step 902 of providing a susceptor ring assembly (such as susceptor ring assembly 100) within a reactor (such as reactor 701) of a reactor system (such as reactor system 700).

Method 900 includes a step 904, which can involve providing a first gas (such as the first gas described above) through at least one injector tube (e.g., a first injector tube (such as first injector tube 126) of the susceptor ring assembly 100 to a lower chamber area (such as lower chamber area 704) of the reactor system 600. During step 704, the first gas can be provided to the reactor system 700 from a first gas source (such as first gas source 140). The first gas source 140 can be an etchant source and/or a purge gas source.

In various embodiments, the first gas source 140 is or comprises an etchant source and delivers an etchant to the lower chamber area 704. If the first gas source 140 comprises providing an etchant, the temperature of reactor 701 can be about 400° C. to about 1200° C., about 500° C. to about 1000° C., or about 500° C. to about 700° C. A pressure within the reaction chamber can be about 10 torr to about 1 ATM, about 10 torr to about 750 torr, or about 10 torr to about 500 torr. A flowrate of the etchant can be about 0.1 slm to about 20 slm, about 0.1 slm to about 10 slm, or about 0.1 slm to about 5 slm.

In various embodiments, the first gas source 140 is or comprises a purge gas source and can deliver a purge gas to the lower chamber area 704. If the first gas source 140 comprises providing a purge gas, the temperature of reactor 701 can be about 400° C. to about 1200° C., about 500° C. to about 1000° C., or about 500° C. to about 700° C. A pressure within the reaction chamber can be about 10 torr to about 1 ATM, about 10 torr to about 750 torr, or about 10 torr to about 500 torr. A flowrate of the etchant can be about 1 slm to about 100 slm, or about 5 slm to about 80 slm.

The first gas in step 904 is provided to the first injector tube 126. The first gas can be configured to flow from the first injector tube 126 to the one or more first outlets 122 and exit the one or more first outlets 122 radially towards the susceptor bottom surface 117 and the lift pins 124.

In additional embodiments, the step 904 can include flowing the first gas through a second injector tube (such as second injector tube 226). The first gas can be configured to flow from the second injector tube 226 to the one or more second outlets 222 and exit the one or more second outlets 222 radially towards the susceptor bottom surface 117 and the lift pins 124.

In some cases, a gas provided to the first and/or second injector tubes 126, 226 can include the same gas(es). In some cases, a gas provided to the first and/or second injector tubes 126, 226 can be the same gas provided to an injection flange (such as injection flange 710). In some cases, the gas provided to the first and/or second injector tubes 126, 226 can include different mixture ratio of the same gases or a subset of gases, of the gases provided to the inlet flange, or can be or include another (e.g. inert) gas.

In further embodiments, the gas can be provided to the one or more first outlets 122 and the one or more second outlets 222 independently of each other—or not. In other words, in some cases, a flow rate of the first gas can be independently controlled for each injector tube.

Method 900 includes a step 906, which can involve providing a second gas to an upper chamber area (such as upper chamber area 702) of the reactor 701. The second gas can be introduced to the upper chamber area 702 by an injection flange (such as injection flange 710) through a gas inlet (such as gas inlet 712). Gas inlet 712 is in fluid communication with the first gas source 140 and a second gas source (such as second gas source 750). In step 906, the second gas can be provided to the reactor 701 from either the first gas source 140 or the second gas source 750. In various embodiments, the second gas can comprise an etchant or a purge gas as described above. The reactor 701 can also comprise the same temperature and pressure specifications as those in step 904. In various embodiments, step 904 and step 906 can be done at the same time or at different times.

Method 900 includes a step 908, which can involve providing a third gas to an upper chamber area 702 (such as upper chamber area 702) of the reactor 701. The third gas can be introduced to the upper chamber area 702 by the injection flange 710 through gas inlet 712. In step 908, the third gas can be provided to the reactor 701 from the second gas source 750. In various embodiments, the third gas can comprise a precursor as described above. The reactor 701 can also comprise the same temperature and pressure specifications as those in step 904. During step 908, the reactor 701 temperature can be about 350° C. to about 950° C., about 350° C. to about 800° C., or about 600° C. to about 800° C. A pressure within the reactor 701 can be about 2 Torr to about 1 ATM, about 2 Torr to about 400 Torr, or about 2 Torr to about 200 Torr. A flowrate of the third gas can be about 10 sccm to about 990 sccm, or 10 sccm to about 700 sccm; either flowrate can be with or without a carrier gas.

By way of examples, methods in accordance with the disclosure can include: (1) performing an upper chamber area clean (also referred to as an etch) and a lower chamber area clean and/or purge—either sequentially or overlapping in time; (2) performing a precoat and/or seasoning (e.g., of a siliconOcontaining material, such as silicon or silicon germanium) in an upper chamber area and a lower chamber area etch and/or purge—either sequentially or overlapping in time; (3) depositing a layer (e.g. an epitaxial layer) on a substrate in an upper chamber area and performing a lower chamber area etch/clean or purge—either sequentially or overlapping in time.

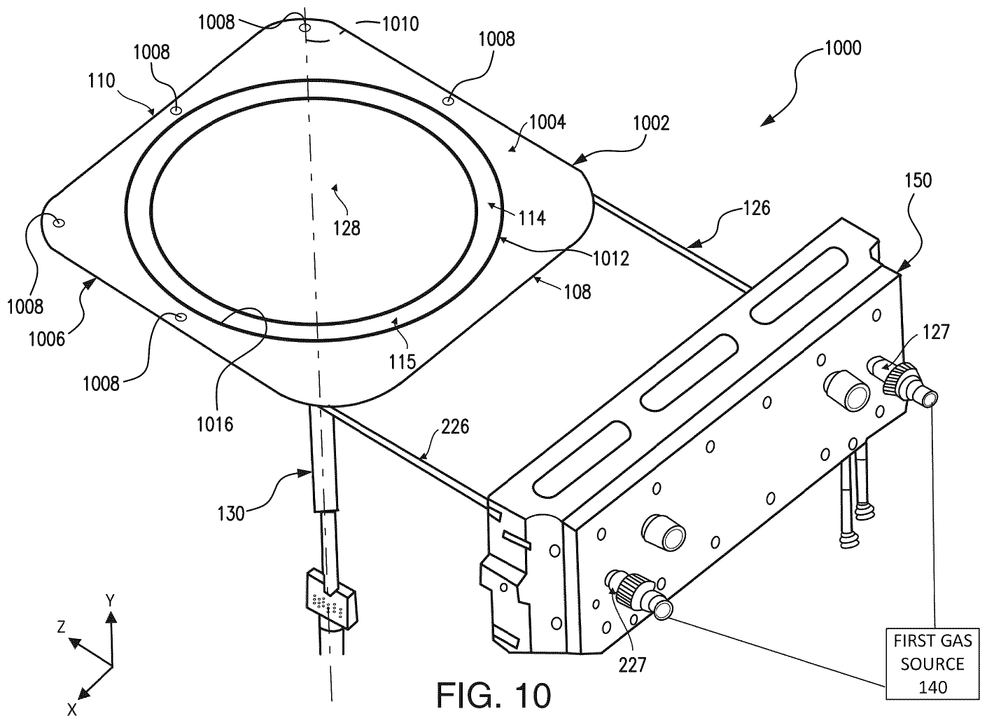

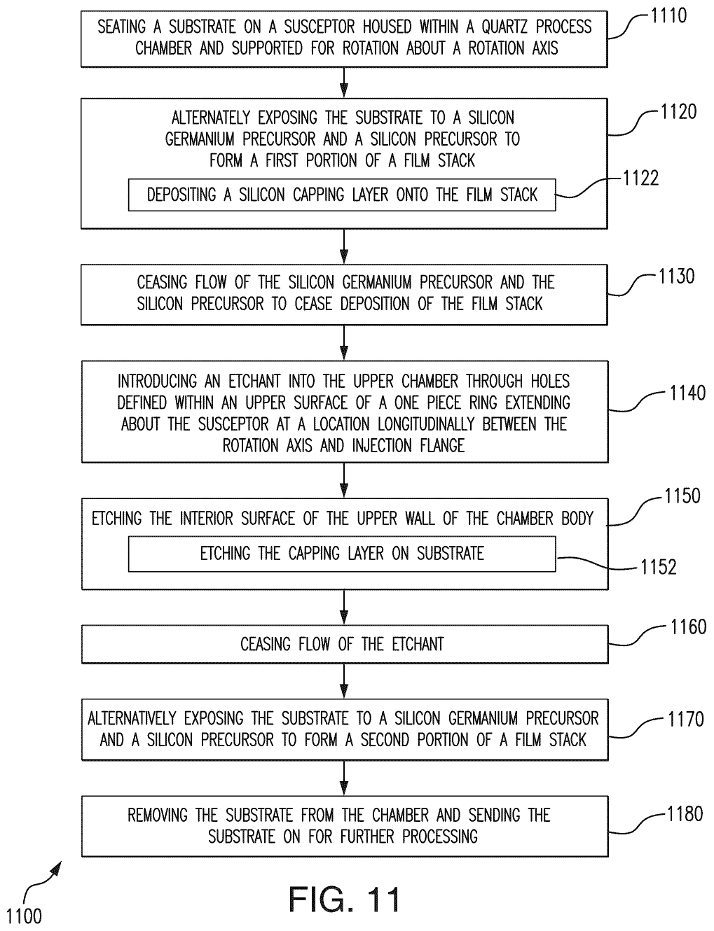

With reference to FIGS. 10 and 11, a susceptor ring assembly 1000 and a material layer deposition method are shown, respectively. As shown in FIG. 10, the susceptor ring assembly 1000 is similar to the susceptor ring assembly 100 (shown in FIG. 1) and additionally includes susceptor ring 1002 having a top surface 1004, a bottom surface 1006, and a sidewall surface 116. The top surface 1004 defines one or more outlet 1008 in fluid communication with either (or both) the first injector tube 126 and the second injector 226 to introduce etchant into the upper area 702 (shown in FIG. 7) of the reactor 701 (shown in FIG. 7). In certain examples, the one or more outlet 1008 may be separated from the exhaust flange 150 by a rotation axis 1010 defined by the shaft member 130. In accordance with certain examples, the one or more outlet 1008 may be separated from the exhaust flange 150 by the susceptor 114 and the substrate 128 seated on the susceptor. It is contemplated that the one or more outlet 1008 may be laterally offset from the rotation axis 1010, and that the one or more outlet 1008 may include an outlet array 1012 distributed on a side of the rotation axis 1012 longitudinally separated from the exhaust flange 150 by the rotation 1012.

During operation, etchant issued from the one or more outlet 1010 may etch an interior surface of the reactor 701. In this respect it is contemplated that etchant issued from the one or more outlet 1008 remove accreted material resident within the upper chamber area 702 to limit (or eliminate) the affect that the accreted material could otherwise have the deposition of the material layer onto the substrate 128. For example, the etchant may restore transmissivity of the reactor 701 by removing accreted material from an interior surface of an upper wall of the reactor 701 above the susceptor ring assembly 1000. As will be appreciated by those of skill in the art in view of the present disclosure, this enables lamps supported outside of the reactor 701 to heat the substrate 128 during deposition of relatively thick material layers and/or maintain optical communication with a pyrometer supported outside of the reactor for temperature control of the substrate, such as superlattices formed from alternating layer pairs of silicon and silicon germanium employed to form 3D DRAM devices, FinFET devices, and GAA devices.

As shown in FIG. 11, the material layer deposition method 1100 may include seating a substrate on a susceptor housed within the a quartz process chamber and supported for rotation therein for rotation about a rotation axis, e.g., the substrate 128 on the susceptor 114, as shown with box 1110. The substrate may be alternately exposed to a silicon germanium precursor and a silicon precursor to form a first portion of a film stack, as shown with box 1120. Flow of the silicon germanium precursor and the silicon precursor may thereafter cease and an etchant introduced into the upper chamber area through outlets defined within an upper surface of a susceptor ring, e.g., the one or more outlet 1008 (shown in FIG. 10) of the susceptor ring 1002 (shown in FIG. 10), as shown with box 1130 and box 1140. An interior surface of an upper wall of the chamber body is etched using the etchant issued into the upper chamber through the one or more outlet defined within the susceptor ring, removing material accreted onto the interior surface of the upper wall of the chamber body during deposition of the film stack onto the substrate, as shown with box 1150. Flow the etchant thereafter ceases, as shown with box 1160, and the substrate again alternately exposed to the silicon germanium precursor and the silicon precursor to form a second portion of the film stack, as shown with box 1170. It is contemplated that the substrate may thereafter be removed from the reactor and sent on to undergo further processing for purposes of forming a desired semiconductor device using the film stack, such as a 3D DRAM device, a FinFET device, or a GAA device, as appropriate, as shown with box 1180.

In certain examples substrate may remain within the reactor during issue of etchant through the one or more opening and removal of accreted material from the interior surface of the upper wall of the chamber body. For example, a silicon capping layer may be deposited onto the first portion of the film stack prior to introduction of the etchant into the chamber, as shown with box 1122, and the capping layer may etched by the etchant issued from the one or more outlet, as shown with box 1152. In this respect it is contemplated that the capping layer may be sized to be sacrificial such that the first portion of the film stack is exposed during the etching of the interior surface of the chamber body. As will be appreciated by those of skill in the art in view of the present disclosure, this can improve throughput of the reactor system by eliminating the need to remove and return the substrate to the reactor subsequent to the etching of the interior surface of the upper wall of the chamber body. As will also be appreciated by those of skill in the art in view of the present disclosure, this can also ensure reliability of semiconductor devices formed using the film stack, for example by limiting (or eliminating) the need to expose the first portion of the film stack to an environment external to the reactor.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A susceptor ring assembly comprising:
a susceptor ring comprising a top surface, a bottom surface, a first edge, a second edge, and a susceptor opening at the interior of the susceptor ring, wherein the first edge comprises an opening extending to a first injector cavity, wherein one or more of the top surface, the bottom surface and a sidewall surface of the susceptor ring comprise one or more first outlets; and
a first injector tube at least partially disposed within the first injector cavity.

2. The susceptor ring assembly of claim 1, wherein the first injector tube comprises quartz.

3. The susceptor ring assembly of claim 1, wherein the susceptor ring comprises a second injector cavity, wherein the susceptor ring assembly comprises a second injector tube disposed therein, and wherein the susceptor ring comprises one or more second outlets.

4. The susceptor ring assembly of claim 1, wherein the one or more first outlets comprise substantially vertical outlets spanning a portion of the bottom surface.

5. The susceptor ring assembly of claim 1, wherein the one or more first outlets comprise substantially horizontal outlets spanning a portion of the sidewall.

6. The susceptor ring assembly of claim 1, wherein the one or more first outlets comprise corner outlets spanning a portion of the bottom surface and a portion of the sidewall.

7. The susceptor ring assembly of claim 1, further comprising a rotatable susceptor at least partially disposed within the susceptor opening.

8. The susceptor ring assembly of claim 1, wherein the first injector tube comprises a first aperture within a wall of the first injector tube.

9. The susceptor ring assembly of claim 8, wherein the first aperture is in fluid communication with at least one of one of the one or more first outlets.

10. A reactor system comprising:
a reactor comprising a reaction chamber comprising an upper chamber area and a lower chamber area;
a susceptor ring assembly disposed within the reactor, the susceptor ring assembly comprising:
a susceptor ring comprising a top surface, a bottom surface, a first edge, a second edge, and a susceptor opening at the interior of the susceptor ring, wherein the first edge comprises an opening extending to a first injector cavity, wherein one or more of the top surface, the bottom surface and a sidewall surface of the susceptor ring comprise one or more first outlets; and
a first injector tube at least partially disposed within the first injector cavity; and
a rotatable susceptor at least partially disposed within the susceptor opening, wherein the rotatable susceptor comprises a susceptor bottom surface.

11. The reactor system of claim 10, further comprising an etchant source fluidly coupled to the first injector tube.

12. The reactor system of claim 10, wherein the reactor system further comprises an exhaust flange coupled to a first end of the reaction chamber.

13. The reactor system of claim 10, wherein the rotatable susceptor comprises one or more lift pin apertures and at least one lift pin is received by one of the one or more lift pin apertures.

14. The reactor system of claim 12, further comprising an injection flange coupled to a second end of the reaction chamber.

15. The reactor system of claim 10, wherein each of the one or more first outlets are below the susceptor bottom surface.

16. The reactor system of claim 10, wherein the first injector tube comprises an aperture configured to provide gas substantially perpendicular to a direction of flow of process gas from the injection flange.

17. The reactor system of claim 10, further comprising a purge gas source fluidly coupled to the first injector tube.

18. A method, comprising the steps of:
providing a susceptor ring assembly within a reactor system, wherein the reactor system comprises a reactor comprising an upper chamber area and a lower chamber area, and the susceptor ring assembly comprises:
a susceptor ring comprising a top surface, a bottom surface, a first edge, a second edge, and a susceptor opening at the interior of the susceptor ring, wherein the first edge comprises an opening extending to a first injector cavity, wherein one or more of the top surface, the bottom surface and a sidewall surface of the susceptor ring comprise one or more first outlets; and
a first injector tube at least partially disposed within the first injector cavity; and
providing a first gas through the first injector tube to the lower chamber area.

19. The method of claim 18, wherein the method further comprises providing a second gas to the upper chamber area during the step of providing the first gas.

20. The method of claim 18, wherein the susceptor ring assembly comprises a rotatable susceptor at least partially disposed within the susceptor opening, wherein the method further comprises providing a substrate on the rotatable susceptor and providing a third gas to the upper chamber area.

21. The method of claim 18, wherein the method further comprises providing a purge gas to the lower chamber area using the first injector tube.

22. The method of claim 18, wherein the reactor further comprises at least one of an etchant source and a purge source fluidly coupled to the first injector tube.
